(19) United States
(12) Patent Application Publication
(10) Pub. No.: US 2015/0069252 A1
(43) Pub. Date: Mar. 12, 2015

(54) X-RAY DETECTOR AND METHOD

(71) Applicant: Siemens Aktiengesellschaft, Munich (DE)

(72) Inventor: Mario EICHENSEER, Hirschaid (DE)

(21) Appl. No.: 14/471,344

(22) Filed: Aug. 28, 2014

(30) Foreign Application Priority Data
Sep. 9, 2013 (DE) 102013217941.3

(51) Int. Cl. G01T 1/29; G01T 1/20; H01L 27/146; G01T 1/24

(52) U.S. Cl. CPC G01T 1/2985; G01T 1/247; G01T 1/241; G01T 1/20; H01L 27/14658
USPC 250/370.09

(57) ABSTRACT

An x-ray detector is disclosed for detection of x-ray radiation, including a planar cathode, an anode divided into a plurality of pixel elements and a direct converter disposed between cathode and anode for conversion of radiation into electrical charge. In an embodiment, at least two guard rings or guard ring structures are disposed around pixel elements or groups of pixel elements, to which guard rings or guard ring structures potentials are applied. Different potentials are applied to at least two different rings of the at least two guard rings or parts of the guard ring structures.

### PRIORITY STATEMENT

The present application hereby claims priority under 35 U.S.C. §119 to German patent application number DE 102013 217941.3 filed Sep. 9, 2013, the entire contents of which are hereby incorporated herein by reference.

### FIELD

At least one embodiment of the invention generally relates to an x-ray detector for detection of x-ray radiation, and/or a method for adapting the radiation response of different pixel elements of an x-ray detector.

### BACKGROUND

For the detection of Gamma and x-ray radiation, especially in computed tomography, angiography, single photon emission computed tomography (SPECT), positron emission tomography (PET) etc., some of the radiation detectors being developed are based on direct-converting materials. Typical materials for direct converters are materials such as III-V or II-VI semiconductors such as cadmium telluride or cadmium zinc telluride. For the detection of x-ray radiation the direct converters are provided with electrodes (cathode and anode) and a high voltage is applied. Through the electrical field charge carriers generated by the (x-ray) radiation are separated, accelerated to the electrodes and can be measured as current.

In order to achieve a spatial resolution of the x-ray detector, one of the electrodes (in general the anode) is typically pixelated, i.e. divided into a plurality of subsurfaces (pixel elements). Furthermore pixel structures, e.g. groups of a number of pixel elements (e.g. 4×4) are enclosed by what is known as a guard ring, to which a specific potential is applied. Guard rings are described in U.S. Pat. No. 6,928,144 B2 for example. Guard rings generally serve to improve the behavior of edge pixels of an x-ray detector or detector module, in that leakage currents and electrical field distortions are partly compensated for. Despite this, pixel elements which are located at the edge of a radiation detector or even just at the edge of a detector module frequently show a radiation response behavior deviating from central pixel elements. A further problem of these types of radiation detectors consists of pixel elements behaving differently depending on whether and in what form an anti-scatter grid structure is located above them. In US 2012/0267737 A1 the edge character of pixel elements is taken into account by one of the two electrodes (e.g. the upper cathode) being extended beyond the substrate.

### SUMMARY

At least one embodiment of the present invention is directed to an x-ray detector which takes account of different x-ray response behavior of pixel elements, e.g. in relation to their edge location and/or the influence on them by anti-scatter grids; and also at least one embodiment is directed to a corresponding method.

An x-ray detector for detection of x-ray radiation is disclosed. Further, a method is disclosed for balancing the x-ray response of different pixel elements of an x-ray detector. Advantageous embodiments of the invention are the subject matter of the corresponding dependent claims.

At least one embodiment of the inventive x-ray detector for detection of x-ray radiation, includes a planar cathode, an anode divided into a plurality of pixel elements and a direct converter disposed between cathode and anode for conversion of radiation into electrical charge. At least two guard rings or guard ring structures are disposed around pixel elements or groups of pixel elements, to which guard rings or guard ring structures electrical potentials are applied. Different electrical potentials are applied to at least two different rings of the at least two guard rings or parts of the guard ring structures, is capable, through different electrical potentials able to be applied by way of guard rings or guard ring structures, of balancing out the radiation response behavior of edge pixel elements, pixel elements with few direct neighboring pixel elements or pixel elements adversely affected in another way and of contributing in this way to an even and high-quality imaging. This thus gives the advantage of better being able to counter the different behavior of the pixel elements, e.g. as regards embodiment of the spatial charge or polarization, which arise because of the ambient conditions (e.g. through anti-scatter grid, edge without neighbors etc.), in order ultimately to make possible a homogeneous response of an x-ray detector and thus artifact-free imaging.

A method is disclosed for balancing the x-ray response of different pixel elements of at least one embodiment of an x-ray detector, wherein as a function of the position of the pixel elements adjacent to the part of the guard ring structure within the x-ray detector or as a function of a anti-scatter grid structure of an anti-scatter grid upstream of the x-ray detector, different potentials are applied to the guard rings or parts of the guard ring structures.

### BRIEF DESCRIPTION OF THE DRAWINGS

The invention as well as further advantageous embodiments in accordance with features of the subclaims will be explained in greater detail below in the drawing on the basis of schematically illustrated example embodiments, without this restricting the invention to these example embodiments. In the figures:

FIG. shows a view of a known computed tomography device with an x-ray detector,

FIG. 2 shows a view of x-ray detector with a known guard ring structure, and

FIG. 3 shows a view of a section of an embodiment of an inventive x-ray detector with a guard ring structure with different potentials applied to it.

### DETAILED DESCRIPTION OF THE EXAMPLE EMBODIMENTS

Various example embodiments will now be described more fully with reference to the accompanying drawings in which only some example embodiments are shown. Specific structural and functional details disclosed herein are merely representative for purposes of describing example embodiments. The present invention, however, may be embodied in many alternate forms and should not be construed as limited to only the example embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the present invention to the particular forms disclosed. On the contrary, example embodiments are to cover all modifications, equivalents, and alternatives falling within the scope of the invention. Like numbers refer to like elements throughout the description of the figures.

Before discussing example embodiments in more detail, it is noted that some example embodiments are described as processes or methods depicted as flowcharts. Although the flowcharts describe the operations as sequential processes, many of the operations may be performed in parallel, concurrently or simultaneously. In addition, the order of operations may be re-arranged. The processes may be terminated when their operations are completed, but may also have additional steps not included in the figure. The processes may correspond to methods, functions, procedures, subroutines, subprograms, etc.

Methods discussed below, some of which are illustrated by the flow charts, may be implemented by hardware, software, firmware, middleware, microcode, hardware description languages, or any combination thereof. When implemented in software, firmware, middleware or microcode, the program code or code segments to perform the necessary tasks will be stored in a machine or computer readable medium such as a storage medium or non-transitory computer readable medium. A processor(s) will perform the necessary tasks.

Specific structural and functional details disclosed herein are merely representative for purposes of describing example embodiments of the present invention. This invention may, however, be embodied in many alternate forms and should not be construed as limited to only the embodiments set forth herein.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

Portions of the example embodiments and corresponding detailed description may be presented in terms of software, or algorithms and symbolic representations of operation on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulations of physical quantities. Usually, though not necessarily, these quantities take the form of optical, electrical, or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

In the following description, illustrative embodiments may be described with reference to acts and symbolic representations of operations (e.g., in the form of flowcharts) that may be implemented as program modules or functional processes include routines, programs, objects, components, data structures, etc., that perform particular tasks or implement particular abstract data types and may be implemented using existing hardware at existing network elements. Such existing hardware may include one or more Central Processing Units (CPUs), digital signal processors (DSPs), application-specific-integrated-circuits, field programmable gate arrays (FPGAs) computers or the like.

Note also that the software implemented aspects of the example embodiments may be typically encoded on some form of program storage medium or implemented over some type of transmission medium. The program storage medium (e.g., non-transitory storage medium) may be magnetic (e.g., a floppy disk or a hard drive) or optical (e.g., a compact disk read only memory, or “CD ROM”), and may be read only or random access. Similarly, the transmission medium may be twisted wire pairs, coaxial cable, optical fiber, or some other suitable transmission medium known to the art. The example embodiments not limited by these aspects of any given implementation.

It should be borne in mind, however, that all of these and similar terms are to be associated with the appropriate physical quantities and are merely convenient labels applied to these quantities. Unless specifically stated otherwise, or as is apparent from the discussion, terms such as “processing” or “computing” or “calculating” or “determining” of “displaying” or the like, refer to the action and processes of a computer system, or similar electronic computing device/hardware, that manipulates and transforms data represented as physical, electronic quantities within the computer system's registers and memories into other data similarly represented as physical quantities within the computer system memories or registers or other such information storage, transmission or display devices.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein are interpreted accordingly.

Although the terms first, second, etc. may be used herein to describe various elements, components, regions, layers and/or sections, it should be understood that these elements, components, regions, layers and/or sections should not be limited by these terms. These terms are used only to distinguish one element, component, region, layer, or section from another region, layer, or section. Thus, a first element, component, region, layer, or section discussed below could be termed a second element, component, region, layer, or section without departing from the teachings of the present invention.

At least one embodiment of the inventive x-ray detector for detection of x-ray radiation, includes a planar cathode, an anode divided into a plurality of pixel elements and a direct converter disposed between cathode and anode for conversion of radiation into electrical charge. At least two guard rings or guard ring structures are disposed around pixel elements or groups of pixel elements, to which guard rings or guard ring structures electrical potentials are applied. Different electrical potentials are applied to at least two different rings of the at least two guard rings or parts of the guard ring structures, is capable, through different electrical potentials able to be applied by way of guard rings or guard ring structures, of balancing out the radiation response behavior of edge pixel elements, pixel elements with few direct neighboring pixel elements or pixel elements adversely affected in another way and of contributing in this way to an even and high-quality imaging. This thus gives the advantage of better being able to counter the different behavior of the pixel elements, e.g. as regards embodiment of the spatial charge or polarization, which arise because of the ambient conditions (e.g. through anti-scatter grid, edge without neighbors etc.), in order ultimately to make possible a homogeneous response of an x-ray detector and thus artifact-free imaging.

Guard rings and guard ring structures can comprise a small group (e.g. macropixels of four, nine or 16 pixel elements), a plurality or even just individual pixel elements in each case.

In accordance with an embodiment of the invention, the x-ray detector has a plurality of guard rings or guard ring structures to which at least two different electrical potentials are applied.

In accordance with a further embodiment of the invention, depending on the position of the pixel elements adjacent to the guard ring or the guard ring structure within the radiation detector, different electrical potentials are applied to the guard rings or to parts of the guard ring structures. In particular in such cases the part of the guard ring structure which is adjacent to edge pixel elements of the x-ray detector has an electrical potential different from the part of the guard ring structure which is adjacent to pixel elements surrounded on all sides by neighboring pixel elements. In this way the different behavior of edge pixel elements compared to center pixel elements can be compensated for and balanced out. In such cases there can be provision if required for the potential in the area of the edge pixel elements to be higher or lower than in the area of the central pixel elements. Also the basic arrangements of the differences of the applied electrical potentials can be adjusted in such cases as required; e.g. the different electrical potentials can differ from each other by a factor of one or two.

Edge pixel elements are understood here as pixel elements which are either disposed at the edge of the overall x-ray detector but also at the edge of detector modules or other detector sections and which, because of their position, e.g. with square pixel elements, have less than eight direct neighboring pixel elements, i.e. only five or three neighboring pixel elements, for example. Central pixel elements have eight direct neighboring pixel elements. The position dependence of the potential of the adjacent guard ring structure can also apply for pixel elements which are not direct edge pixel elements; thus these can also only lie in the vicinity of the detector edge or detector module edge and still have a different electrical guard ring potential to centrally-disposed pixel elements. In this context for example different electrical potentials can be applied in stages to parts of guard ring structures between edge pixel elements and pixel elements disposed centrally on the x-ray detector (detector module or similar).

In accordance with a further embodiment of the invention, depending on an anti-scatter grid structure of an anti-scatter grid placed in front of the x-ray detector, different potentials are applied to the guard rings or parts of the guard ring structures. The respective potentials of the guard rings or of the guard ring structure are thus selected as a function of whether an anti-scatter grid is present and how this is embodied and disposed in relation to the respective pixel elements. In particular the part of the guard ring structure which is adjacent to pixel elements at least partly shadowed by the anti-scatter grid structure has a different electrical potential from the part of the guard ring structure which is adjacent to non-shadowed pixel elements. Here too the different radiation response behavior of the corresponding at least partly shadowed pixel elements can be compensated for by suitable electrical potentials of the guard ring structures. Here too the electrical potentials can be selected accordingly as required, e.g. higher or lower for shadowed pixel elements, in corresponding orders of magnitude, e.g. by a factor of one or two. Different shadowing can be compensated for by different electrical potentials for example.

The direct converter is embodied from a III-V or II-VI semiconductor, especially from cadmium telluride or cadmium zinc telluride (CZT).

In accordance with a further embodiment of the invention, the x-ray detector is embodied as a CT x-ray detector for computed tomography imaging. These types of CT x-ray detectors are frequently embodied in the shape of a curve and have one or more rows of detector modules consisting of a plurality of pixel elements. In general, a plurality of mostly narrow slice images irradiated by an x-ray beam are captured from different projection directions, which are then subsequently reconstructed at the processor. CT x-ray detectors are generally constructed from a plurality of detector modules, which in their turn have a plurality of pixel elements.

In accordance with a further embodiment of the invention, the x-ray detector is embodied as a flat panel detector, e.g. for fluoroscopy or angiography imaging. These types of flat panel detector are embodied in a rectangular flat shape.

A known computed tomography device 10 with a CT x-ray detector 11 is shown in FIG. 1. The computed tomography device 10 comprises a patient support table 12 for supporting a patient to be examined, a gantry not shown in the figure with a recording system 14; 11 supported rotatably around a system axis 13. The recording system 14; 11 has an x-ray tube 14 and the x-ray detector 11, which are aligned opposite one another so that x-ray radiation emanating during operation from the focus 15 of the x-ray tube 14 strikes the x-ray detector 11. The x-ray detector 11 comprises an anti-scatter grid 16, a direct converter 17 between cathode not shown and pixelated anode and readout electronics 18 lying behind them in the radiation direction. The x-ray detector 11 has a number of pixel elements or detector elements grouped into detector modules 19, for example. X-ray quanta are thus able to be counted spatially-resolved and/or detected energy-selectively. For recording an image of an examination region, on rotation of the recording system 14; 11 around the system axis 13, projections are captured from a plurality of different projection directions. The generated image data is subsequently transmitted to an image processor 20 with a reconstruction unit 21, which reconstructs an image from the image data, e.g. in the form of a slice image of the patient in accordance with known methods. The image can be displayed on a display unit 22 connected to the image processor 20.

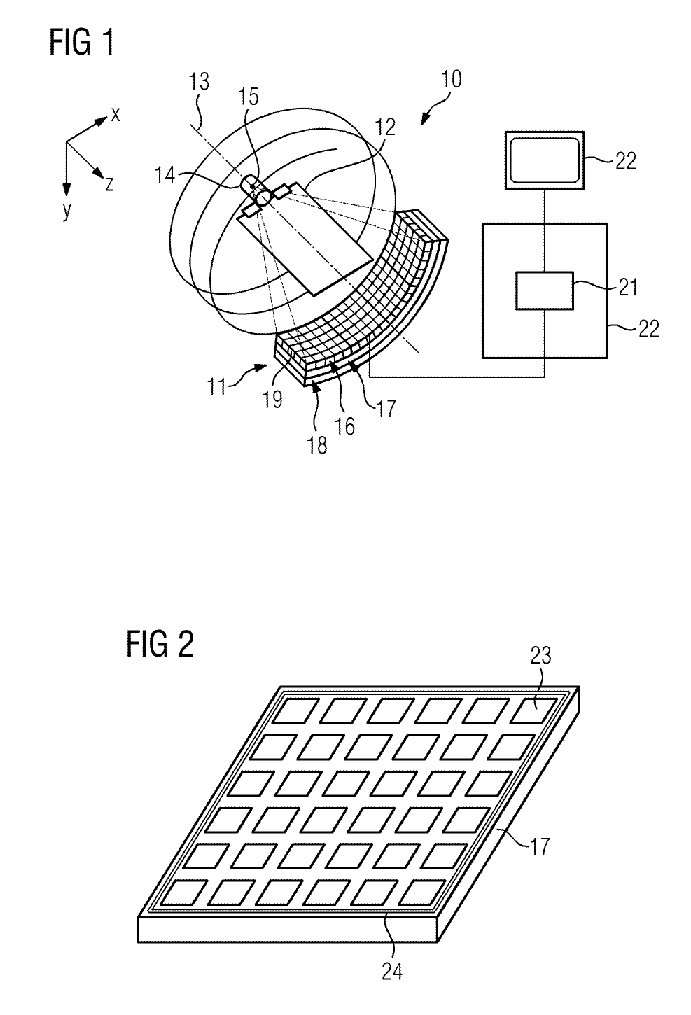

An example for a group of pixel elements 23, which are enclosed by a known guard ring 24, is shown in FIG. 2. Guard rings 24 or guard ring structures can comprise a group of pixel elements, individual pixel elements or also a plurality of pixel elements, e.g. in the form of a whole detector module. Guard rings can be applied as conductor track or conductor points of a conductive material (e.g. gold, platinum or another metal) to the side of the pixelated anode of the pixel element. By means of corresponding circuitry an electrical potential is applied to the guard ring or the guard ring structure. Known x-ray detectors have guard rings to which basically the same potential is applied.

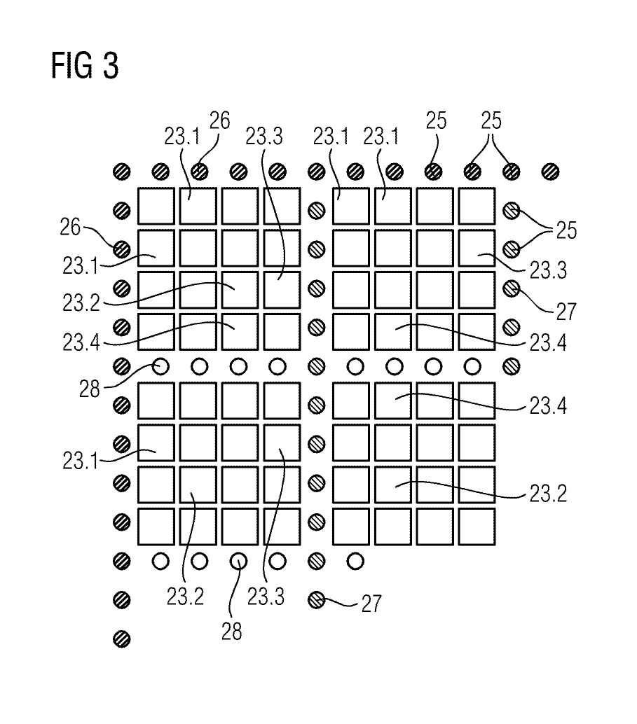

FIG. 3 shows a section of an embodiment of an inventive x-ray detector with a guard ring structure 25 to which different electrical potentials are applied. A part of the guard ring structure, which comprises the edge pixel elements 23.1 of a subunit of the x-ray detector (for example of a detector module or of a sensor board or of the entire x-ray detector) or is adjacent to this, is set to a first electrical potential 26 (filled-out points) in order to compensate for the edge character of the edge pixel elements. The potential is selected such that the edge pixel elements in their behavior, i.e. in relation to their radiation response behavior for example, balance the embodiments to a spatial charge or polarization or similar at central pixel elements 23.2. Another part of the guard ring structure 25, which is adjacent to pixel elements 23.3 shadowed by the anti-scatter grid for example, has a second electrical potential 27 different from the first electrical potential 26 (semi-filled points). In addition a further part of the guard ring structure 25 which is adjacent to pixel elements 23.4 greatly shadowed by the anti-scatter grid, has a further electrical potential 28 (non-filled points) applied to it, wherein the third potential 28 differs from the two other potentials.

As an alternative many different embodiments of the invention are conceivable. For example a guard ring can be also applied around each pixel element for example, wherein here two different potentials, e.g. depending on the position of the pixel element enclosed in each case, are provided. Or guard rings are present in each case around groups of pixel elements, e.g. 4×4 pixel elements (macropixels), which then in the case of an “edge” group (at the edge of the x-ray detector or detector module or sensor board or the like) have an electrical potential different from the guard rings of central macropixels.

Also for example only the part of the guard ring structure which encloses the edge pixel elements of a sub unit of the x-ray detector (for example a detector module or a sensor board or the entire x-ray detector) or is adjacent to the latter can have a first electrical potential applied to it, while the other guard ring structure has a second potential different from this potential.

By applying different electrical potentials as a function of the spatial position of the guard ring structure ultimately a homogeneous response of an x-ray detector and thus artifact-free imaging can be made possible.

An embodiment of the invention can be briefly summarized in the following way: for a homogeneous and where possible artifact-free imaging an x-ray detector for detection of x-ray radiation, having a planar cathode, an anode divided into a plurality of pixel elements and a direct converter disposed between cathode and anode for conversion of radiation into electrical charge is provided, wherein at least two guard rings or guard ring structures are disposed around pixel elements or groups of pixel elements, to which guard rings or guard ring structures potentials are applied, wherein different potentials are applied to at least two different rings of the at least two guard rings or parts of the guard ring structures.

The patent claims filed with the application are formulation proposals without prejudice for obtaining more extensive patent protection. The applicant reserves the right to claim even further combinations of features previously disclosed only in the description and/or drawings.

The example embodiment or each example embodiment should not be understood as a restriction of the invention. Rather, numerous variations and modifications are possible in the context of the present disclosure, in particular those variants and combinations which can be inferred by the person skilled in the art with regard to achieving the object for example by combination or modification of individual features or elements or method steps that are described in connection with the general or specific part of the description and are contained in the claims and/or the drawings, and, by way of combinable features, lead to a new subject matter or to new method steps or sequences of method steps, including insofar as they concern production, testing and operating methods.

References back that are used in dependent claims indicate the further embodiment of the subject matter of the main claim by way of the features of the respective dependent claim; they should not be understood as dispensing with obtaining independent protection of the subject matter for the combinations of features in the referred-back dependent claims. Furthermore, with regard to interpreting the claims, where a feature is concretized in more specific detail in a subordinate claim, it should be assumed that such a restriction is not present in the respective preceding claims.

Since the subject matter of the dependent claims in relation to the prior art on the priority date may form separate and independent inventions, the applicant reserves the right to make them the subject matter of independent claims or divisional declarations. They may furthermore also contain independent inventions which have a configuration that is independent of the subject matters of the preceding dependent claims.

Further, elements and/or features of different example embodiments may be combined with each other and/or substituted for each other within the scope of this disclosure and appended claims.

Still further, any one of the above-described and other example features of the present invention may be embodied in the form of an apparatus, method, system, computer program, tangible computer readable medium and tangible computer program product. For example, of the aforementioned methods may be embodied in the form of a system or device, including, but not limited to, any of the structure for performing the methodology illustrated in the drawings.

Even further, any of the aforementioned methods may be embodied in the form of a program. The program may be stored on a tangible computer readable medium and is adapted to perform any one of the aforementioned methods when run on a computer device (a device including a processor). Thus, the tangible storage medium or tangible computer readable medium, is adapted to store information and is adapted to interact with a data processing facility or computer device to execute the program of any of the above mentioned embodiments and/or to perform the method of any of the above mentioned embodiments.

The tangible computer readable medium or tangible storage medium may be a built-in medium installed inside a computer device main body or a removable tangible medium arranged so that it can be separated from the computer device main body. Examples of the built-in tangible medium include, but are not limited to, rewriteable non-volatile memories, such as ROMs and flash memories, and hard disks. Examples of the removable tangible medium include, but are not limited to, optical storage media such as CD-ROMs and DVDs; magneto-optical storage media, such as MOs; magnetism storage media, including but not limited to floppy disks (trademark), cassette tapes, and removable hard disks; media with a built-in rewriteable non-volatile memory, including but not limited to memory cards; and media with a built-in ROM, including but not limited to ROM cassettes; etc. Furthermore, various information regarding stored images, for example, property information, may be stored in any other form, or it may be provided in other ways.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

1. An x-ray detector for detection of x-ray radiation comprising:
a planar cathode;
an anode divided into a plurality of pixel elements; and
a direct converter, disposed between cathode and anode, to convert x-ray radiation into electrical charge, at least two guard rings or guard ring structures being disposed on the pixel elements or on groups of the pixel elements, to which guard ring or guard ring structure potentials are to be applied, wherein different potentials are to be applied to at least two different rings of the at least two guard rings or parts of the guard ring structures.

2. The x-ray detector of claim 1, wherein the at least two guard rings or guard ring structures include a plurality of guard rings or guard ring structures to which at least two different potentials are appliable.

3. The x-ray detector of claim 1, wherein, within the x-ray detector, different potentials are applied to the guard rings or parts of the guard ring structures depending on relative position of respective pixel elements adjacent to the respective guard ring or the guard ring structure.

4. The x-ray detector of claim 1, wherein, depending on an anti-scatter grid structure of an anti-scatter grid upstream of the x-ray detector, different potentials are appliable to the guard rings or parts of the guard ring structures.

5. The x-ray detector of claim 3, wherein a part of the guard ring structure, adjacent to edge pixel elements of the x-ray detector, includes a different potential from a part of the guard ring structure adjacent on all sides to pixel elements surrounded by neighboring pixel elements.

6. The x-ray detector of claim 4, wherein a part of the guard ring structure, adjacent to the pixel elements at least partly shadowed by the anti-scatter grid structure, includes a different potential from the part of the guard ring structure adjacent to non-shadowed pixel elements.

7. The x-ray detector of claim 1, wherein the direct converter is formed from cadmium telluride or cadmium zinc telluride.

8. The x-ray detector of claim 1, wherein the x-ray detector is embodied as a CT x-ray detector for computed tomography.

9. The x-ray detector of claim 1, wherein the x-ray detector is embodied as a flat panel detector.

10. A method for balancing the x-ray response of different pixel elements of the x-ray detector of claim 1, comprising:
applying, as a function of the position of the pixel elements adjacent to the part of the guard ring structure within the x-ray detector or as a function of a anti-scatter grid structure of an anti-scatter grid upstream of the x-ray detector, different potentials to the guard rings or parts of the guard ring structures.

11. The x-ray detector of claim 2, wherein, within the x-ray detector, different potentials are applied to the guard rings or parts of the guard ring structures depending on relative position of respective pixel elements adjacent to the respective guard ring or the guard ring structure.

12. The x-ray detector of claim 2, wherein, depending on an anti-scatter grid structure of an anti-scatter grid upstream of the x-ray detector, different potentials are appliable to the guard rings or parts of the guard ring structures.

13. The x-ray detector of claim 3, wherein, depending on an anti-scatter grid structure of an anti-scatter grid upstream of the x-ray detector, different potentials are appliable to the guard rings or parts of the guard ring structures.

14. A method for balancing the x-ray response of different pixel elements of the x-ray detector of claim 2, comprising:
applying, as a function of the position of the pixel elements adjacent to the part of the guard ring structure within the x-ray detector or as a function of a anti-scatter grid structure of an anti-scatter grid upstream of the x-ray detector, different potentials to the guard rings or parts of the guard ring structures.

15. A method for balancing the x-ray response of different pixel elements of the x-ray detector of claim 3, comprising:
applying, as a function of the position of the pixel elements adjacent to the part of the guard ring structure within the x-ray detector or as a function of a anti-scatter grid structure of an anti-scatter grid upstream of the x-ray detector, different potentials to the guard rings or parts of the guard ring structures.

16. A method for balancing the x-ray response of different pixel elements of the x-ray detector of claim 4, comprising:
applying, as a function of the position of the pixel elements adjacent to the part of the guard ring structure within the x-ray detector or as a function of a anti-scatter grid structure of an anti-scatter grid upstream of the x-ray detector, different potentials to the guard rings or parts of the guard ring structures.
